(19) United States
(12) Patent Application Publication
(10) Pub. No.: US 2013/0056068 A1
(43) Pub. Date: Mar. 7, 2013

(54) PREPARATION METHOD OF FLEXIBLE ELECTRODES AND FLEXIBLE DYE-SENSITIZED SOLAR CELLS USING THE SAME

(71) Applicants: Min-Jae KO, Seoul (KR); Hong-Gon KIM, Seoul (KR); Doh-Kwon LEE, Seoul (KR); Kyung-Kon KIM, Seoul (KR); Bong-Soo KIM, Seoul (KR); Ki-Cheon YOO, Seoul (KR)

(72) Inventors: Min-Jae KO, Seoul (KR); Hong-Gon KIM, Seoul (KR); Doh-Kwon LEE, Seoul (KR); Kyung-Kon KIM, Seoul (KR); Bong-Soo KIM, Seoul (KR); Ki-Cheon YOO, Seoul (KR)

(73) Assignee: KOREA INSTITUTE OF SCIENCE AND TECHNOLOGY, Seoul (KR)

(21) Appl. No.: 13/342,808

(22) Filed: Jan. 3, 2012

(30) Foreign Application Priority Data
Sep. 6, 2011 (KR) 1020110090303

(51) Int. Cl. H01L 51/46; H01L 31/18; H01L 31/0203; B82Y 99/00

(52) U.S. Cl. 136/259; 136/263; 438/98; 977/948; 257/E31.124

(57) ABSTRACT

The present invention relates to a method for manufacturing a flexible photoelectrode and a dye-sensitized solar cell using the same. More specifically, the method for manufacturingg a photoelectrode comprises forming a nanoparticle metal oxide layer on a flexible substrate, adsorbing dyes, and then, coating polymer, thereby forming a nanoparticle metal oxide layer consisting of nanoparticle metal oxide-dye-polymer.

According to the present invention, the polymer penetrated between the nanoparticle metal oxide after dye adsorption may increase adhesion to the substrate and improve mechanical properties. Particularly, when applied for a flexible substrate such as a plastic substrate, bending property is excellent, and it may be useful for a flexible dye-sensitized solar cell having durability.

### CROSS-REFERENCE TO RELATED APPLICATION

This application claims priority to and the benefit under 35 U.S.C. §119(a) of a Korean patent application No. 10-2011-0090303 filed on Sep. 6, 2011, the entire disclosure of which is incorporated herein by reference for all purposes.

### BACKGROUND OF THE INVENTION

(a) Field of the Invention

The present invention relates to a method for preparing a flexible photoelectrode comprising a complex of dye-adsorbed nanoparticle metal oxide-polymer, with excellent bending property, and thus excellent durability and mechanical strength, and excellent electrical property, a flexible photoelectrode prepared therefrom, and a flexible dye-sensitized solar cell using the same.

(b) Description of the Related Art

A dye-sensitized solar cell is represented by a photoelectrochemical solar cell announced by Gratzel et al., Swiss, at 1991, and it is generally consisted of photosensitive dye that absorbs visible light, metal oxide nanoparticles having wide band gap, a counter electrode functioning as a catalyst by platinum (Pt), and electrolyte filled therebetween. The dye-sensitized solar cell has advantages that the manufacturing cost is low compared to the existing silicon solar cell or a compound semiconductor solar cell, the efficiency is high compared to an organic solar cell, and it is environment-friendly and may be made transparent.

Particularly, a flexible dye-sensitized solar cell has been in the spotlight in that it may be applied for self-charging of power supply required for the next generation PC industries such as mobile phone, and wearable PC, and the like, or attached to clothes, hat, automobile glass, building, and the like.

However, in the semiconductor electrode (i.e., photoelectrode) of the flexible substrate dye-sensitized solar cell, if external force such as bending is applied, cracks may be easily generated and electrode may be delaminated from the substrate by modification of the flexible substrate due to the structure consisting of interconnected metal nanooxide.

### SUMMARY OF THE INVENTION

To overcome the problems of the prior art, it is an object of the present invention to provide a method for preparing a flexible photoelectrode capable of forming a photoelectrode on a flexible substrate such as plastic and metal by a simple process using polymer.

It is another object of the present invention to provide a flexible photoelectrode prepared by the above method.

It is another object of the present invention to provide a flexible dye-sensitized solar cell having high photoelectric conversion efficiency while securing durability of a semiconductor film layer, using the above flexible photoelectrode as a semiconductor electrode.

The present invention provides a method for preparing a flexible photoelectrode comprising

(a) forming a porous membrane comprising metal oxide nanoparticles on a flexible substrate coated with a conductive film;

(b) adsorbing dyes on the surface of the metal oxide nanoparticles of the porous membrane; and

(c) coating a polymer solution on the dye-adsorbed metal oxide nanoparticles of the porous membrane and heat treating, to prepare a complex of dye-adsorbed metal oxide nanoparticles-polymer where polymer is penetrated between the metal oxide nanoparticles of the porous membrane.

The flexible substrate may be a plastic substrate selected from the group consisting of polyethylene terephthalate; polyethylene naphthalate; polycarbonate; polypropylene; polyimide; triacetylcellulose, polyethersulfone, organically modified silicate of a three dimensional network structure formed by hydrolysis and condensation reaction of organometal alkoxide of at least one selected from the group consisting of methyltriethoxy silane, ethyl triethoxy silane and propyltriethoxysilane; a copolymer thereof; and a mixture thereof, or a metal flexible substrate comprising one selected from the group consisting of iron, stainless steel, aluminum, titanium, nickel, copper and tin.

The porous membrane may include metal oxide nanoparticles selected from the group consisting of tin (Sn) oxide, antimony (Sb), niobium (Nb) or fluorine-doped tin (Sn) oxide, indium (In) oxide, tin-doped indium (In) oxide, zinc (Zn) oxide, aluminum (Al), boron (B), gallium (Ga), hydrogen (H), indium (In), yttrium (Y), titanium (Ti), silicon (Si) or tin (Sn)-doped zinc (Zn) oxide, magnesium (Mg) oxide, cadmium (Cd) oxide, magnesium zinc (MgZn) oxide, indium zinc (InZn) oxide, copper aluminum (CuAl) oxide, silver (Ag) oxide, gallium (Ga) oxide, zinc tin oxide (ZnSnO), titanium (TiO₂) and zinc indium tin (ZIS) oxide, nickel (Ni) oxide, rhodium (Rh) oxide, ruthenium (Ru) oxide, iridium (Ir) oxide, copper (Cu) oxide, cobalt (Co) oxide, tungsten (W) oxide, titanium (Ti) oxide, zirconium (Zr) oxide, strontium (Sr) oxide, lanthanum (La) oxide, vanadium (V) oxide, molybdenum (Mo) oxide, niobium (Nb) oxide, aluminum (Al) oxide, yttrium (Y) oxide, scandium (Sc) oxide, samarium (Sm) oxide, strontium titanium (SrTi) oxide and a mixture thereof.

The present invention also provides a flexible dye-sensitized solar cell comprising

a counter electrode disposed so as to be opposite to the flexible photoelectrode prepared by the above method with spaced apart, and

electrolyte that fills a space between the photoelectrode and the counter electrode,

wherein the photoelectrode comprises a flexible substrate coated with a conductive film, and a complex of dye-adsorbed metal oxide nanoparticle-polymer formed thereon.

### BRIEF DESCRIPTION OF THE DRAWINGS

FIG. 1 schematically shows a process for preparing a complex of metal oxide nanoparticles-polymer of the present invention.

FIG. 2 is a cross-sectional view of a flexible dye-sensitized solar cell according to the present invention.

FIG. 3 shows the electron probe micro-analyzer (EPMA) result for distribution degree of polymer in the metal oxide nanoparticles in Examples 1 to 3 and Comparative Example 1.

FIG. 4 is a graph comparing current-voltage curves of the dye-sensitized solar cells of Examples 1 to 3 and Comparative Example 1.

FIGS. 5a and 5b are graphs comparing current-voltage curves of the dye-sensitized solar cells according to external bending test of Examples 1 to 3 and Comparative Example 1.

FIGS. 6a and 6b are graphs comparing current-voltage curves of the dye-sensitized solar cells according to external bending test of Examples 2 and 5 and Comparative Example 1 and 2-2.

FIG. 7 compares film the states of the dye-sensitized solar cells after external bending test of Example 5(a) and Comparative Example 1(b) of FIG. 6b.

### DETAILED DESCRIPTION OF THE EMBODIMENTS

Hereinafter, the present invention will be explained in detail.

As explained above, according to the manufacturing method of a semiconductor electrode having a flexible substrate of the prior art, photoelectric conversion efficiency of a solar cell may be deteriorated or durability of a film may be decreased.

To overcome the problem, the applicant has developed a method for forming a film by blending polymer with a nanoparticle metal oxide layer (Korean Patent Laid-Open Publication No. 2010-0088310). However, this method has disadvantages that during a process of dye adsorption to nanoparticle metal oxide to be progressed later, a space which may be adsorbed by dyes is already occupied by polymer thus decreasing dye adsorption amount, and the surface of metal nanoparticles is coated with an insulator polymer to disturb electron transfer, thus decreasing current value.

Therefore, the present invention is an improvement in the above method, and provides a method that comprises a dye-adsorbed metal oxide layer-polymer complex that is fired at a low temperature (150° C. or less) and thus giving excellent photoelectric conversion efficiency and flexibility, and thus may be effectively applied for a next generation PC industries such as wearable PC, mobile phone, and the like.

The method of the present invention includes adsorbing dyes on a nanocrystal oxide layer formed on a conductive flexible substrate by low temperature firing at 150° C. or less, and then, applying polymer on the flexible substrate.

Specifically, the present invention forms a nanocrystal oxide layer on a TCO (transparent conducting oxide) substrate such as a conductive flexible substrate to manufacture a photoelectrode, and then, adsorbing dyes on the photoelectrode, and applying polymer thereon. Thus, the present invention may sufficiently secure dye adsorption amount, compared to a method of directly applying a paste comprising polymer on a flexible substrate, and it allows insulator polymer to efficiently progress electron transfer.

Then, referring to the attached drawings, preferable embodiments of the invention will be explained so that a person having ordinary knowledge in the art may easily practice the invention. As will be easily understood by a person having ordinary knowledge in the art, the following examples are only to illustrate the invention and the present invention may be variously modified without departing from the concept and the scope of the invention. Identical or similar parts are indicated by identical reference numerals in the drawings as far as possible.

And, when it is stated that one part is “on” or “on the upper part” of another part, one part may be directly on another part or yet another part may be interposed therebetween. To the contrary, when it is stated that one part is “directly on” another part, yet another part is not interposed therebetween.

Terms used herein are only to illustrate specific embodiments, and the present invention is not limited thereto. As used herein, the term “comprising” embodies specific property, area, integer, step, operation, element and/or ingredient, and it does not exclude the existence or addition of other properties, areas, integers, steps, operations, elements and/or ingredients.

As used herein, the term “nano” refers to a nanoscale, and it may include micro unit. And, the term “nanoparticle” includes any forms of particles having a nanoscale.

As used herein, “a flexible photoelectrode” refers to “a semiconductor electrode having a flexible substrate” that may be used for a dye-sensitized solar cell.

Meanwhile, according to one preferred embodiment of the invention, a method for manufacturing a photoelectrode is provided, which comprises

(a) forming a porous membrane comprising metal oxide nanoparticles on a flexible substrate coated with a conductive film;

(b) adsorbing dyes on the surface of the metal oxide nanoparticles of the porous membrane; and

(c) coating a polymer solution on the dye-adsorbed metal oxide nanoparticles of the porous membrane and heat treating, to prepare a complex of dye-adsorbed metal oxide nanoparticles-polymer where polymer is penetrated between the metal oxide nanoparticels of the porous membrane.

The flexible photoelectrode manufactured by the above method has a photoelectric conversion efficiency decrease rate (%) of 50% or less after 100 to 300 times bending test using a bending tester with a diameter of 7 mm, compared to initial efficiency, and thus, it has very excellent bending property, and excellent durability and mechanical property.

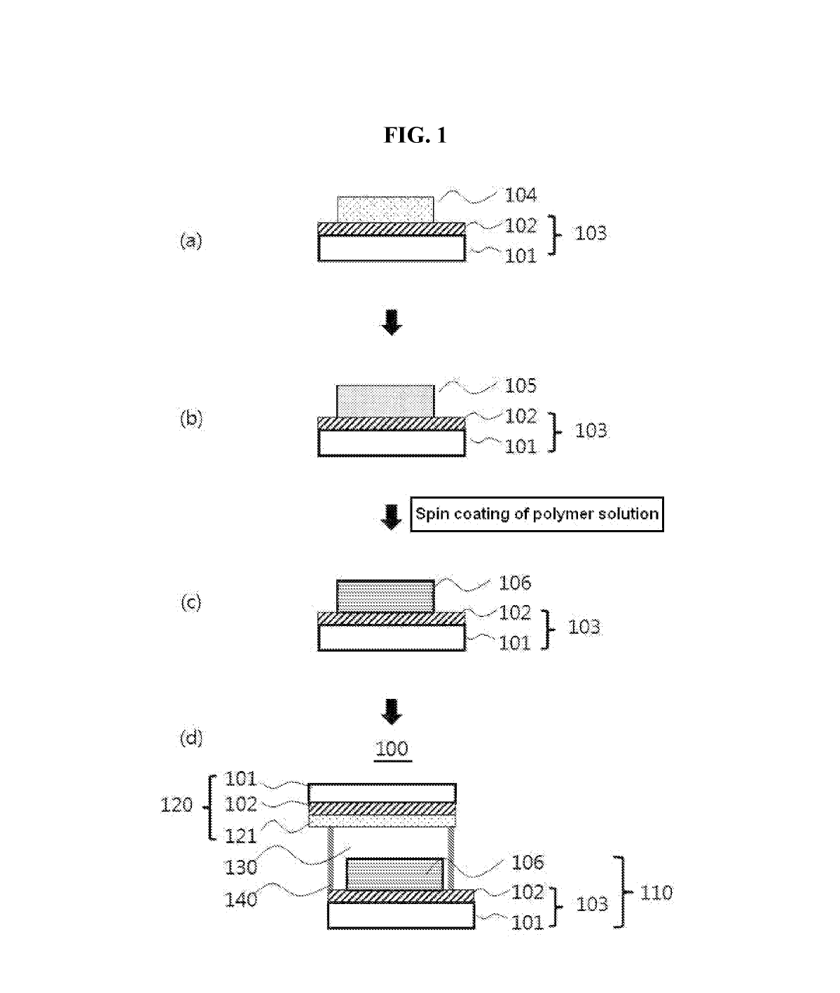

Preferably, the manufacturing method of a flexible photoelectrode of the present invention is as shown in FIG. 1. FIG. 1 is a schematic diagram of a process for explaining a manufacturing method of a flexible photoelectrode and a manufacturing method of a dye-sensitized solar cell comprising the photoelectrode.

Referring to FIG. 1, a conductive flexible substrate (103) is prepared, and a porous membrane (104) comprising metal oxide nanoparticles is formed thereon (FIG. 1, (a)). The conductive flexible substrate (103) means a flexible substrate (101) coated with a conductive film (102).

Then, dyes are adsorbed on the surface of the porous membrane (104) to form a porous membrane (105) comprising dye-adsorbed metal oxide nanoparticles, thus manufacturing a basic photoelectrode (FIG. 1, (b)).

Subsequently, a polymer solution is coated directly on the porous membrane (105) comprising the dye-adsorbed metal oxide nanoparticles, to manufacture a flexible photoelectrode (110) comprising a complex of dye-adsorbed metal oxide nanoparticle-polymer (FIG. 1, (c)). The complex comprises dye-adsorbed metal oxide nanoparticle, and through the process (c), polymer may be penetrated between the metal oxide nanoparticles of the porous membrane comprising dye-adsorbed metal oxide nanoparticles, thus increasing adhesion to a substrate and improving mechanical properties.

Finally, a counter electrode (120) is disposed so as to be oppose to the flexible photoelectrode (110) with spaced apart, and then, electrolyte (130) is injected, and they are sealed with a polymer adhesive (140) to manufacture a flexible dye-sensitized solar cell (100) (FIG. 1, (d)). The counter electrode (120) may comprise a flexible substrate (101), a conductive film (102) and a catalyst layer (121) formed on the flexible substrate.

Meanwhile, the forming of the porous membrane (104) comprising metal oxide nanoparticles in the step (a) may be progressed by a common method for forming a metal oxide nanoparticle layer, except that a binder is not used.

Since the present invention manufactures a plastic dye-sensitized solar cell by firing at low temperature, a binder that is generally used in the existing method of forming a metal oxide nanoparticle layer (for example, polyethyleneglycol, polyethyleneoxide, polyvinyl alcohol, polyvinyl pyrrolidone, ethylcellulose, and the like) is not used. Specifically, the present invention forms a porous membrane with a paste that does not contain a binder, adsorbing dyes, and then, coating a polymer solution thereon, thereby providing a method for manufacturing a plastic dye-sensitized solar cell having strong impact resistance and excellent bending property without efficiency decrease.

For example, a paste comprising the metal oxide nanoparticles and a solvent is prepared, which is then coated on a flexible substrate coated with a conductive film, fired at low temperature of 150° C. or less to form a porous membrane. The paste may be prepared by a well known method without specific limitations. For example, the paste may be prepared by mixing metal oxide nanoparticles with a solvent to prepare a colloidal solution where metal oxide nanoparticles are properly dispersed in an amount of 10˜50 wt %, and then, removing the solvent by distillation. And, the kind and the mixing ratio of the metal oxide nanoparticles and the solvent may be those well known in the art without specific limitations. For example, the solvent may include ethanol, methanol, terpineol, lauric acid, and the like. The metal oxide nanoparticles used for preparing the paste may preferably have a particle size of 10 to 100 nm. The metal oxide nanoparticles may include tin (Sn) oxide, antimony (Sb), niobium (Nb) or fluorine-doped tin (Sn) oxide, indium (In) oxide, tin-doped indium (In) oxide, zinc (Zn) oxide, aluminum (Al), boron (B), gallium (Ga), hydrogen (H), indium (In), yttrium (Y), titanium (Ti), silicon (Si) or tin (Sn)-doped zinc (Zn) oxide, magnesium (Mg) oxide, cadmium (Cd) oxide, magnesium zinc (MgZn) oxide, indium zinc (InZn) oxide, copper aluminum (CuAl) oxide, silver (Ag) oxide, gallium (Ga) oxide, zinc tin oxide (ZnSnO), titanium (TiO₂) and zinc indium tin (ZIS) oxide, nickel (Ni) oxide, rhodium (Rh) oxide, ruthenium (Ru) oxide, iridium (Ir) oxide, copper (Cu) oxide, cobalt (Co) oxide, tungsten (W) oxide, titanium (Ti) oxide, zirconium (Zr) oxide, strontium (Sr) oxide, lanthanum (La) oxide, vanadium (V) oxide, molybdenum (Mo) oxide, niobium (Nb) oxide, aluminum (Al) oxide, yttrium (Y) oxide, scandium (Sc) oxide, samarium (Sm) oxide, strontium titanium (SrTi) oxide, and a mixture thereof, and preferably titanium oxide.

The coating of the paste for forming the porous membrane in the step (a) may be performed by screen printing, and the like, but a common coating method such as doctor blade, and the like may be used without specific limitation.

The adsorption of dyes in the step (b) may be progressed by impregnating the flexible substrate on which a porous membrane comprising metal oxide nanoparticles is formed in a solution comprising photosensitive dyes for 10 minutes to 24 hours.

By this method, a primary photoelectrode having a structure wherein a porous membrane comprising dye-adsorbed metal oxide nanoparticles is formed on a flexible substrate may be manufactured.

The photosensitive dye may include those having Band Gap of 1.55 eV to 3.1 eV thus capable of absorbing visible light, and for example, it may include organic-inorganic complex dye comprising metal or metal complex, organic dye, and a mixture thereof. The organic-inorganic complex dye may include those comprising an element selected from the group consisting of aluminum (Al), platinum (Pt), palladium (Pd), europium (Eu), lead (Pb), iridium (Ir), ruthenium (Ru), and a complex thereof.

And, in the (c), a secondary photoelectrode on which a complex of dye-adsorbed metal oxide nanoparticles-polymer is formed may be manufactured by spin coating a polymer solution on the dye-adsorbed primary photoelectrode. The complex of dye-adsorbed metal oxide nanoparticles-polymer may preferably comprise a complex of dye-adsorbed metal oxide nanoparticles-polymethylmethacrylate. And, the porous membrane comprising the dye-adsorbed metal oxide nanoparticles may have porosity of 30 to 80%.

Particularly, the preparing of the dye-adsorbed metal oxide nanoparticles-polymer complex in the step (c) may be conducted by forming a porous membrane comprising dye-adsorbed metal oxide nanoparticles on a flexible substrate and coating a polymer solution thereon.

The polymer solution may be preferably a colloidal solution wherein 0.01 to 10 wt % of polymer is dispersed in a solvent, based on the total polymer solution. The polymer solution may be prepared by a common method without specific limitation. For example, it may be prepared as a colloidal solution in which 0.01˜10 wt % of polymer is properly dispersed by mixing the polymer in a solvent and uniformly agitating. And, if necessary, the mixing ratio of the polymer and the solvent may be modified, but the above ratio is preferable.

The polymer finally remains in an electrode, differently from a common binder used for preparing a paste. The polymer may include those well known in the art without specific limitation. Preferably, the polymer may include polyurethane, polyethylenoxide (PEO), polypropyleneoxide, polyvinylpyrrolidone, polyethyleneglycol (PEG), chitosan, chitin, polyacrylamide, polyvinyl alcohol, polyacrylic acid, ethyl cellulose, polyhydroxyethylmethacrylicacid (PHEMA), polymethylmethacrylate, cellulose, polysaccharide, polyamide, polycarbonate, polyethylene, polypropylene, polystyrene, polyethyleneterephthalate (PET), polyethylenenaphthalate (PEN), silicon containing polymer comprising polydimethylsiloxane (PDMS), isoprene, butadiene-based rubber, and a derivative thereof, and preferably polymethylmethacrylate, polyvinylpyrrolidone, and polyethylenoxide (PEO).

The solvent used for preparing of the polymer solution may include those capable of dissolving polymer such as ethanol, methanol, terpineol, lauric acid, ethyl acetate, hexane, toluene, and the like, but not limited thereto.

And, the coating of the polymer solution may be preferably conducted by spin coating, slit coating or dip coating. And, the thickness of the coating may be 1 to 100 nm, but not limited thereto.

After the coating of the polymer solution, heat treatment may be conducted at room temperature to 150° C. or less for 10 to 30 minutes. Preferably, the heat treatment may be conducted at a temperature of from 20° C. to 150° C. for 10 to 30 minutes.

And, the flexible substrate coated with a conductive film, which is used for preparing a flexible photoelectrode, may be a transparent plastic substrate or a metal flexible substrate.

Preferably, the plastic substrate may be selected from the group consisting of polyethylene terephthalate; polyethylene naphthalate; polycarbonate; polypropylene; polyimide; triacetylcellulose, polyethersulfone, organically modified silicate of a three dimensional network structure formed by hydrolysis and condensation reaction of organometal alkoxide of at least one selected from the group consisting of methyltriethoxy silane, ethyl triethoxy silane and propyltriethoxysilane; a copolymer thereof; and a mixture thereof. The metal flexible substrate may comprise one selected from the group consisting of iron, stainless steel, aluminum, titanium, nickel, copper and tin.

The conductive film may comprise SnO₂:F, ITO, a metal electrode having an average thickness of 1 to 1000 nm, metal nitride, metal oxide, a carbon compound, or conductive polymer

The metal nitride may be selected from the group consisting of nitride of Group IVB metal atom including titanium (Ti), zirconium (Zr) and hafnium (Hf); nitride of Group VB metal atom including niobium (Nb), tantalum (Ta) and vanadium (V); nitride of Group VIB metal atom including chromium (Cr), molybdenum (Mo) and tungsten (W); aluminum nitride, gallium nitride, indium nitride, silicon nitride, germanium nitride, and a mixture thereof.

The metal oxide may be selected from the group consisting of tin (Sn) oxide, antimony (Sb), niobium (Nb) or fluorine-doped tin (Sn) oxide, indium (In) oxide, tin-doped indium (In) oxide, zinc (Zn) oxide, aluminum (Al), boron (B), gallium (Ga), hydrogen (H), indium (In), yttrium (Y), titanium (Ti), silicon (Si) or tin (Sn)-doped zinc (Zn) oxide, magnesium (Mg) oxide, cadmium (Cd) oxide, magnesium zinc (MgZn) oxide, indium zinc (InZn) oxide, copper aluminum (CuAl) oxide, silver (Ag) oxide, gallium (Ga) oxide, zinc tin oxide (ZnSnO), titanium oxide (TiO₂) and zinc indium tin (ZIS) oxide, nickel (Ni) oxide, rhodium (Rh) oxide, ruthenium (Ru) oxide, iridium (Ir) oxide, copper (Cu) oxide, cobalt (Co) oxide, tungsten (W) oxide, titanium (Ti) oxide, and a mixture thereof.

The carbon compound may be selected from the group consisting of activated carbon, graphite, carbon nanotube, carbon black, graphene, and a mixture thereof.

The conductive polymer may be selected from the group consisting of PEDOT (poly(3,4-ethylenedioxythiophene)-PSS(poly(styrenesulfonate)), polyaniline-CSA, pentacene, polyacetylene, P3HT (poly(3-hexylthiophene), polysiloxane carbazole, polyaniline, polyethylene oxide, (poly(1-methoxy-4-(0-Disperse Red1)-2,5-phenylene-vinylene), polyindol, poycarbazol, polypyridiazine, polyisothianaphthalene, polyphenylene sulfide, polyvinylpyridine, polythiophene, polyfluorene, polypyridine, polypyrrol, polysulfurnitride, and a copolymer thereof

The complex of dye-adsorbed metal oxide nanoparticles-polymer prepared by the above method allows polymer to penetrate between the dye-adsorbed metal oxide nanoparticles and thus, the polymer may provide adhesion to the substrate. And, the complex of dye-adsorbed metal oxide nanoparticles-polymer may comprise a porous membrane having porosity of 30 to 80%.

Meanwhile, according to another embodiment of the invention, a flexible dye-sensitized solar cell is provided, which comprises a counter electrode disposed so as to be opposite to the flexible photoelectrode prepared by the above method with spaced apart, and electrolyte that fills a space between the photoelectrode and the counter electrode, wherein the photoelectrode comprises a flexible substrate coated with a conductive film, and a dye-adsorbed metal oxide nanoparticle-polymer complex formed thereon.

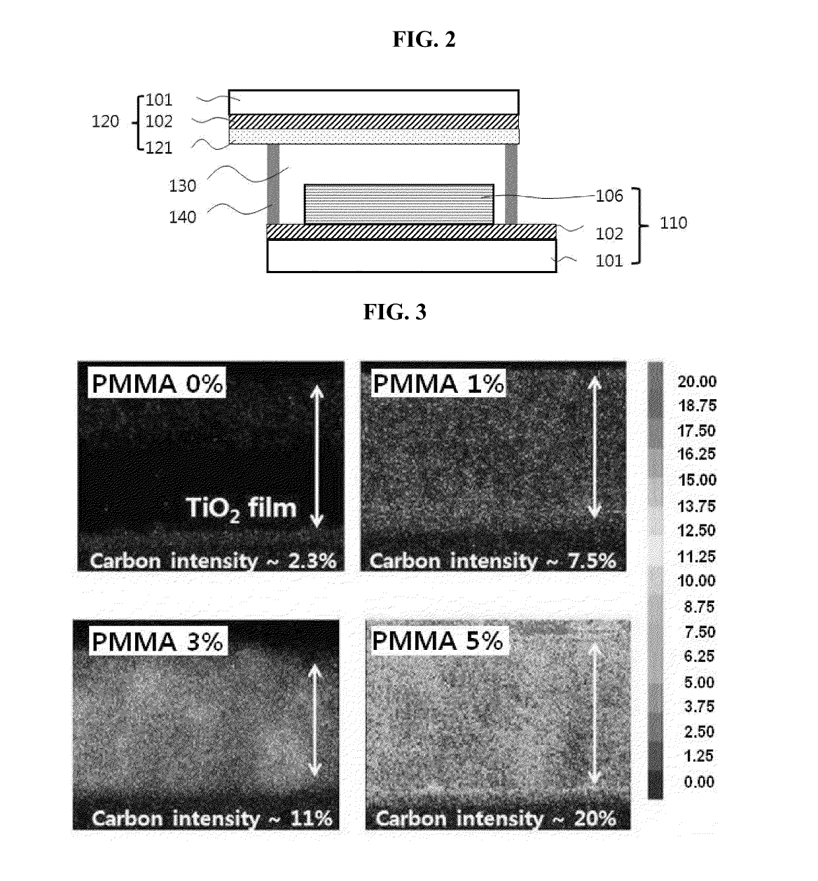

FIG. 2 schematically shows a cross-section of a flexible dye-sensitized solar cell according to one embodiment of the invention. The structure of the flexible dye-sensitized solar cell of FIG. 2 is only to illustrate the invention, and the present invention is not limited thereto,

As shown in FIG. 2, the dye-sensitized solar cell according to one embodiment of the invention comprises a flexible substrate (101) coated with a conductive film (102), a photoelectrode (110) comprising a complex of dye-adsorbed metal oxide nanoparticles-polymer, a counter electrode (120) disposed so as to be oppose to the photoelectrode (110), electrolyte (130) filled between the two electrodes, and a polymer adhesive (140) for sealing them.

The counter electrode (120) may comprise a flexible substrate (101), and a conductive film (102) and a catalyst layer (121) formed on the flexible substrate. The catalyst layer refers to a nanoparticle metal film formed of Pt, and the like so as to form a part constituting the counter electrode. The catalyst layer may comprise at least one selected from the group consisting of platinum (Pt), activated carbon, graphite, carbon nanotube, carbon black, p-type semiconductor, (poly(3,4-ethylenedioxythiophene)) (PEDOT)-(poly(styrenesulfonate)) (PSS), polyaniline-CSA, pentacene, polyacetylene, (poly(3-hexylthiophene) (P3HT), polysiloxane carbazole, polyaniline, polyethylene oxide, poly(1-methoxy-4-(0-Disperse Red1)-2,5-phenylene-vinylene, polyindol, polycarbazol, polypyridiazine, polyisothianaphthalene, polyphenylene sulfide, polyvinylpyridine, polythiophene, polyfluorene, polypyridine, polypyrrole, polysulfunitride, and a derivative thereof, a copolymer thereof, and a mixture thereof.

The conductive film (102) refers to a transparent conducting oxide (TCO) that may be formed on a flexible substrate (101), and it may include SnO₂:F or ITO, graphene, carbon nanotube, and the like, but not limited thereto, and a common conductive film well known in the art may be formed on a flexible substrate.

The flexible substrate (101) forming the counter electrode (120) may be the same transparent plastic substrate or metal flexible substrate such as stainless steel, Ti, and the like, as used for preparing the photoelectrode.

And, the thicknesses of the flexible substrate, conductive film and catalyst layer of the counter electrode are not specifically limited.

Although the electrolyte (130) is shown to be simply filled for convenience of explanation, practically, it may be uniformly dispersed in a complex layer of metal oxide nanoparticles-polymer, which is a porous membrane (106), between the photoelectrode (110) and the counter electrode (120).

The electrolyte may be selected from the group consisting of an oxidation-reduction derivative, polymer gel electrolyte containing polymer or inorganic particles, organic hole conductor (HCM, Spiro-OMeTAD) and P type semiconductor (CuSCN).

Namely, the electrolyte comprises an oxidation-reduction derivative which functions for receiving electrons from the counter electrode and transferring them to dyes of the photoelectrode by oxidation-reduction, and it is not specifically limited as long as it may be used for a common dye-sensitized solar cell. Specifically, the oxidation-reduction derivative may be preferably selected from the group consisting of iodine (I), bromine (Br), cobalt (Co), thiocyanate (SCN—), selenium cyanate (SeCN—)-type containing electrolyte. And, the polymer gel electrolyte may contain at least one polymer selected from the group consisting of polyvinylidene fluoride-co-polyhexafluoropropylene, polyacrylonitrile, polyethylene oxide, and polyalkyl acrylate. And, the inorganic particle-containing polymer gel electrolyte may contain at least one inorganic particles selected from the group consisting of silica and TiO₂ nanoparticle. And, the electrolyte may comprise an organic hole conductor (HCM, spiro-OMeTAD) and P-type semiconductor (CuSCN).

The solar cell may further comprise a heat adhesion polymer film (140) or paste adhesive for sealing the semiconductor electrode and the counter electrode, and the adhesive may include commonly used adhesives without specific limitation.

According to the present invention, a photoelectrode comprising a complex of nanoparticle metal oxide-polymer may be easily manufactured at low temperature by spin coating. Thus, current value may be increased due to higher dye adsorption amount, compared to the existing method of blending polymer. And, when bending or other external force is applied to the formed electrode, polymer may support nanoparticle metal oxide, compared to the existing electrode consisting only of inorganic substances. Therefore, the present invention may manufacture a flexible dye-sensitized solar cell having excellent impact resistance, excellent durability to bending and mechanical strength, while having excellent photoelectric conversion efficiency equivalent to the existing solar cell.

Hereinafter, the present invention will be explained with reference to the following Examples. However, these examples are illustrated to aid understanding of the invention, and the scope of the invention is not limited thereto.

### Examples 1 to 3

### Manufacture of a Photoelectrode

As a substrate for photoelectrode, a conductive plastic substrate (Peccell Technologies, Inc. material: PEN/ITO, thickness 200 μm, 15 Ω/sq, a substrate comprising (101) and (102) of FIG. 2) was prepared. Subsequently, a solution formed by dispersing 8 g of TiO₂ nanoparticles (average diameter 20 nm) in 200 ml of ethanol was agitated (40 minutes/450 rpm) with a mechanical agitator to prepare a uniform colloidal solution. To increase the viscosity of the solution, the solvent was distilled at 50° C., 170 rpm using a rotary evaporator to prepare a paste. The paste was coated on a plastic substrate (ITO/PEN) by doctor blade method, and then, heat treated at 100° C. for 2 hours to remove the solvent thus manufacturing an electrode with a thickness of 6 μm.

Subsequently, the complex electrode was impregnated with an ethanol solution comprising 0.5 mM of ruthenium (Ru) type photosensitive dye N719 (bis(tetrabutylammonium)-cis-(dithiocyanato-N,N′-bis(4-carboxylato-4′-carboxylic acid-2,2′-bipyridine)ruthenium(II)) at 50° C. for 1 hour to adsorb the photosensitive dyes on the surface of the nanoparticles of the porous metal oxide layer.

And then, polymethylmethacrylate (PMMA) polymer was dissolved in ethyl acetate (EA) to prepare a polymer solution (colloidal solutions each containing 1, 3 and 5 wt % of PMMA). The prepared polymer solution was dropped on a dye-adsorbed metal oxide nanoparticle layer, and allowed to stand for 1 to 10 minutes so that the polymer may be penetrated into the nanoparticle metal oxide, and then, spin coated at 2000 rpm and heat treated at 25° C. for 10 minutes. Through these processes, the polymer was penetrated in the porous membrane of the dye-adsorbed nanoparticle metal oxide to prepare a complex of nanoparticel metal oxide-polymer. And, they are respectively designated as Examples 1 to 3 according to the polymer content.

(Manufacture of Counter Electrode)

As a substrate for a counter electrode, a film formed by coating Pt/Ti alloy on a conductive plastic substrate to a thickness of 30 nm (Peccell Technologies Inc., material: PEN, thickness 188 μm, 5 Ω/sq) was used (a counter electrode (120) consisting of (101), (102) and (121) of FIG. 2).

(Injection of Electrolyte and Sealing)

Into a space between the above manufactured photoelectrode and counter electrode, acetonitrile electrolyte comprising PMII (1-methyl-3-propylimidazolium iodide, 0.7M) and I₂ (0.03M) was injected, and the electrodes were sealed with polymer resin to manufacture a dye-sensitized solar cell with the structure of FIG. 2.

### Examples 4 to 6

### Manufacture of Photoelectrode

As a substrate for photoelectrode, a conductive plastic substrate (Peccell Technologies, Inc. material: PEN/ITO, thickness 200 μm, 15 Ω/sq, a substrate comprising (101) and (102) of FIG. 2) was prepared. Subsequently, a solution formed by dispersing 8 g of TiO₂ nanoparticles (average diameter 20 nm) in 200 ml of ethanol was agitated (40 minutes/450 rpm) with a mechanical agitator to prepare a uniform colloidal solution. To increase the viscosity of the solution, the solvent was distilled at 50° C., 170 rpm using a rotary evaporator to prepare a paste. The paste was coated on a plastic substrate (ITO/PEN) by doctor blade method, and then, heat treated at 100° C. for 2 hours to remove the solvent thus manufacturing an electrode with a thickness of 6 μm.

Subsequently, the complex electrode was impregnated with an ethanol solution comprising 0.5 mM of ruthenium (Ru) type photosensitive dye N719 (bis(tetrabutylammonium)-cis-(dithiocyanato-N,N′-bis(4-carboxylato-4′-carboxylic acid-2,2′-bipyridine)ruthenium(II)) at 50° C. for 1 hour to adsorb the photosensitive dyes on the surface of the nanoparticles of the porous metal oxide layer.

And then, polyvinyl pyrrolidone (PVP) polymer was dissolved in ethyl acetate (EA) to prepare a polymer solution (colloidal solutions each containing 1, 5 and 10 wt % of PVP). The prepared polymer solution was dropped on a dye-adsorbed metal oxide nanoparticle layer, and allowed to stand for 1 to 10 minutes so that the polymer may be penetrated into the nanoparticle metal oxide, and then, spin coated at 2000 rpm and heat treated at 25° C. for 10 minutes. Through these processes, the polymer was penetrated in the porous membrane of the dye-adsorbed nanoparticle metal oxide to prepare a complex of nanoparticel metal oxide-polymer. And, they are respectively designated as Examples 4 to 6 according to the polymer content.

(Manufacture of Counter Electrode)

As a substrate for a counter electrode, a film formed by coating Pt/Ti alloy on a conductive plastic substrate to a thickness of 30 nm (Peccell Technologies Inc., material: PEN, thickness 188 μm, 5 Ω/sq) was used (a counter electrode (120) consisting of (101), (102) and (121) of FIG. 2).

(Injection of Electrolyte and Sealing)

Into a space between the above manufactured photoelectrode and counter electrode, acetonitrile electrolyte comprising PMII (1-methyl-3-propylimidazolium iodide, 0.7M) and I₂ (0.03M) was injected, and the electrodes were sealed with a common polymer resin to manufacture a dye-sensitized solar cell with the structure of FIG. 2.

### Comparative Example 1

### Manufacture of Photoelectrode

As a substrate for photoelectrode, a conductive plastic substrate (Peccell Technologies, Inc. material: PEN/ITO, thickness 200 μm, 15 Ω/sq, a substrate comprising (101) and (102) of FIG. 2) was prepared. Subsequently, a solution formed by dispersing 8 g of TiO₂ nanoparticles (average diameter 20 nm) in 200 ml of ethanol was agitated (40 minutes/450 rpm) with a mechanical agitator to prepare a uniform colloidal solution. To increase the viscosity of the solution, the solvent was distilled at 50° C., 170 rpm using a rotary evaporator to prepare a paste. The paste was coated on a plastic substrate (ITO/PEN) by doctor blade method, and then, heat treated at 100° C. for 2 hours to remove the solvent thus manufacturing an electrode with a thickness of 6 μm.

Subsequently, the complex electrode was impregnated with an ethanol solution comprising 0.5 mM of ruthenium (Ru) type photosensitive dye N719 (bis(tetrabutylammonium)-cis-(dithiocyanato-N,N′-bis(4-carboxylato-4′-carboxylic acid-2,2′-bipyridine)ruthenium(II)) at 50° C. for 1 hour to adsorb the photosensitive dyes on the surface of the nanoparticles of the porous metal oxide layer, thus manufacturing a photoelectrode.

(Manufacture of Counter Electrode)

As a substrate for a counter electrode, a film formed by coating Pt/Ti alloy on a conductive plastic substrate to a thickness of 30 nm (Peccell Technologies Inc., material: PEN, thickness 188 μm, 5 Ω/sq) was used (a counter electrode (120) consisting of (101), (102) and (121) of FIG. 2).

(Injection of Electrolyte and Sealing)

Into a space between the above manufactured photoelectrode and counter electrode, acetonitrile electrolyte comprising PMII (1-methyl-3-propylimidazolium iodide, 0.7M) and I₂ (0.03M) was injected, and the electrodes were sealed with a common polymer resin to manufacture a dye-sensitized solar cell with the structure of FIG. 2.

### Comparative Example 2

A dye-sensitized solar cell was manufactured according to a method described in Korean Registered Patent No. 10-1034640.

(Manufacture of Photoelectrode)

As a substrate for a photoelectrode, a conductive plastic substrate (Peccell Technologies, Inc. material: PEN/ITO, thickness 200 μm, 15 Ω/sq) was prepared.

Subsequently, a solution formed by dispersing 8 g of TiO₂ nanoparticles (average diameter 20 nm) in 200 ml of ethanol and a solution formed by introducing polymer (polymethylmethacrylate (PMMA)) in acetic acid were agitated (40 minutes/450 rpm) with a mechanical agitator to prepare a uniform colloidal solution. To increase the viscosity of the solution, the solvent was distilled at 50° C., 170 rpm using a rotary evaporator to prepare a paste. The paste was coated on a plastic substrate (ITO/PEN) by doctor blade method, and then, heat treated at 100° C. for 2 hours to remove the solvent thus manufacturing an electrode with a thickness of 6 μm.

Subsequently, the complex electrode was impregnated with an ethanol solution comprising 0.5 mM of ruthenium (Ru) type photosensitive dye N719 (bis(tetrabutylammonium)-cis-(dithiocyanato-N,N′-bis(4-carboxylato-4′-carboxylic acid-2,2′-bipyridine)ruthenium(II)) at 50° C. for 1 hour to adsorb the photosensitive dyes on the surface of the nanoparticles of the porous metal oxide layer, thus manufacturing a photoelectrode. And, they are respectively designated as Comparative Examples 2-1 to 2-3 according to the polymer content.

(Manufacture of Counter Electrode)

As a substrate for a counter electrode, a film formed by coating Pt/Ti alloy on a conductive plastic substrate to a thickness of 30 nm (Peccell Technologies Inc., material: PEN, thickness 188 μm, 5 Ω/sq) was used.

(Injection of Electrolyte and Sealing)

Into a space between the above manufactured photoelectrode and counter electrode, acetonitrile electrolyte comprising PMII (1-methyl-3-propylimidazolium iodide, 0.7M) and I₂ (0.03M) was injected, and the electrodes were sealed with a common polymer resin to manufacture a dye-sensitized solar cell.

### Experimental Example 1

To examine distribution degree of polymer in the metal oxide nanoparticles, polymer dispersion degrees of the flexible photoelectrodes of the dye-sensitized solar cell of Examples 1 to 3 and Comparative Example 1 were measured using carbon EPMA (electron probe micro-analyzer). The results are shown in FIG. 3. As shown in FIG. 3, in Comparative Example 1 which does not comprise polymer (PMMA), carbon density is low and polymer is not distributed. To the contrary, when coating is progressed with a solution comprising 1 to 5 wt % of polymer (PMMA) as Examples 1 to 3, carbon density is increased and polymer is uniformly distributed. Therefore, the polymer may support dye-adsorbed metal oxide nanoparticles, and thus, if external force is applied to the substrate, excellent photoelectric conversion efficiency may be maintained due to excellent durability and impact resistance.

### Experimental Example 2

For each dye-sensitized solar cell manufactured in Comparative Examples 1 and 2 and Examples 1 to 6, open circuit voltage, photocurrent density, energy conversion efficiency, and fill factor were measured as follows, and the results are shown in the following Table 1.

(1) open circuit voltage (V) and photocurrent density (mA/cm²)
Open circuit voltage and photocurrent density were measured with Keithley SMU2400.

(2) energy conversion efficiency (%) and fill factor (%)
Energy conversion efficiency was measured with a solar simulator of 1.5 AM 100 mW/cm² (consisting of Xe lamp [1600W, YAMASHITA DENSO], AM1.5 filter, and Keithley SMU2400), and fill factor was calculated using the above obtained conversion efficiency and the following Formula.

$$Fill factor ( \% ) = \frac{( J \times V ) max}{Jsc \times Voc} \times 100 \qquad [ Formula ]$$

In the above Formula, J is the Y axis value of conversion efficiency curve, V is the X axis value of conversion efficiency curve, and Jsc and Voc are intercepts of each axis.

### Experimental Example 3

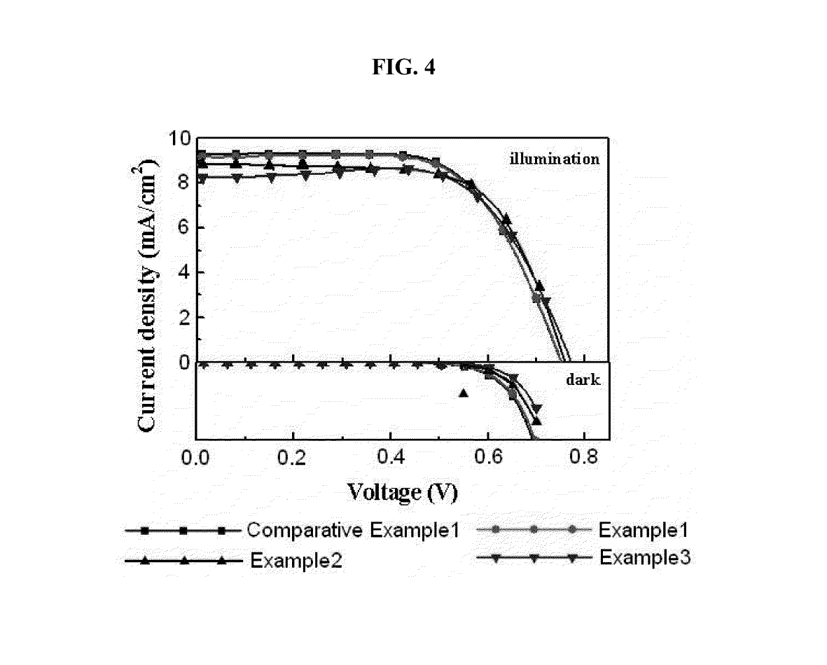

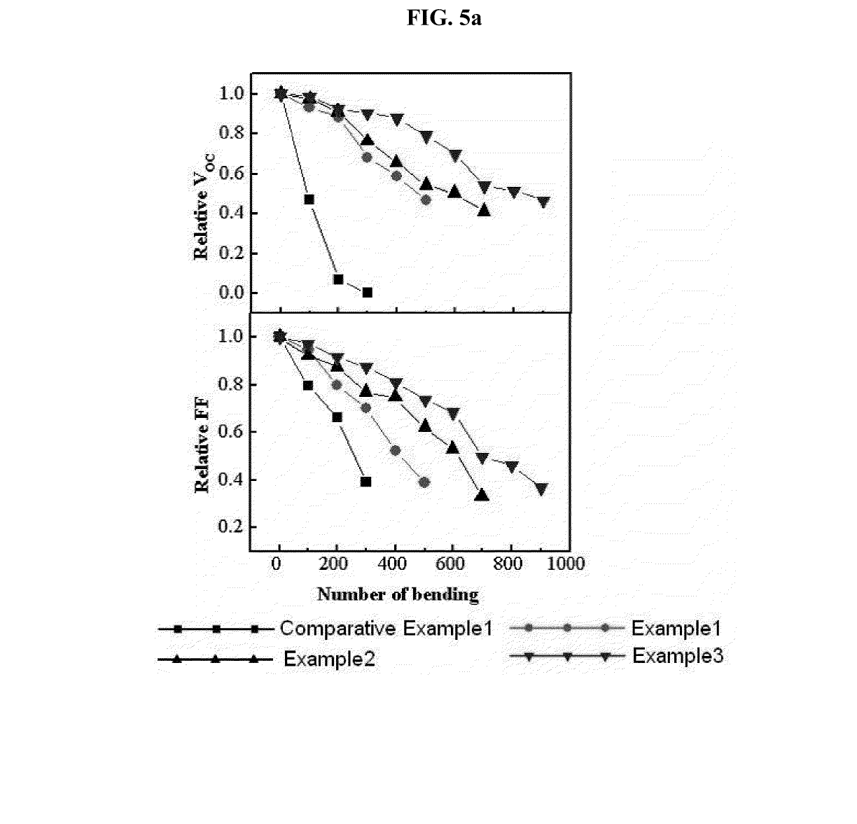

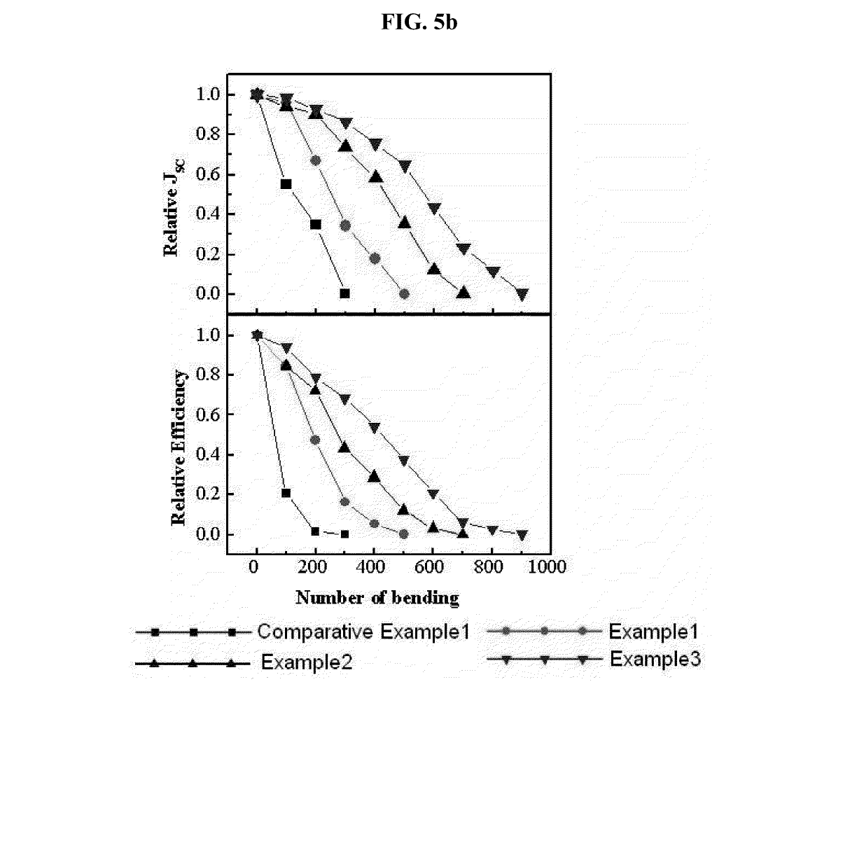

For each dye-sensitized solar cell manufactured in Comparative Example 1 and Examples 1 to 3, open circuit voltage, photocurrent density, energy conversion efficiency, and fill factor are shown in FIG. 4. And, current-voltage curves of Examples 1 to 3 and Comparative Example 1 according to bending test under AM 1.5G 1 Sun are shown in FIGS. 5a and 5b.

### Experimental Example 4

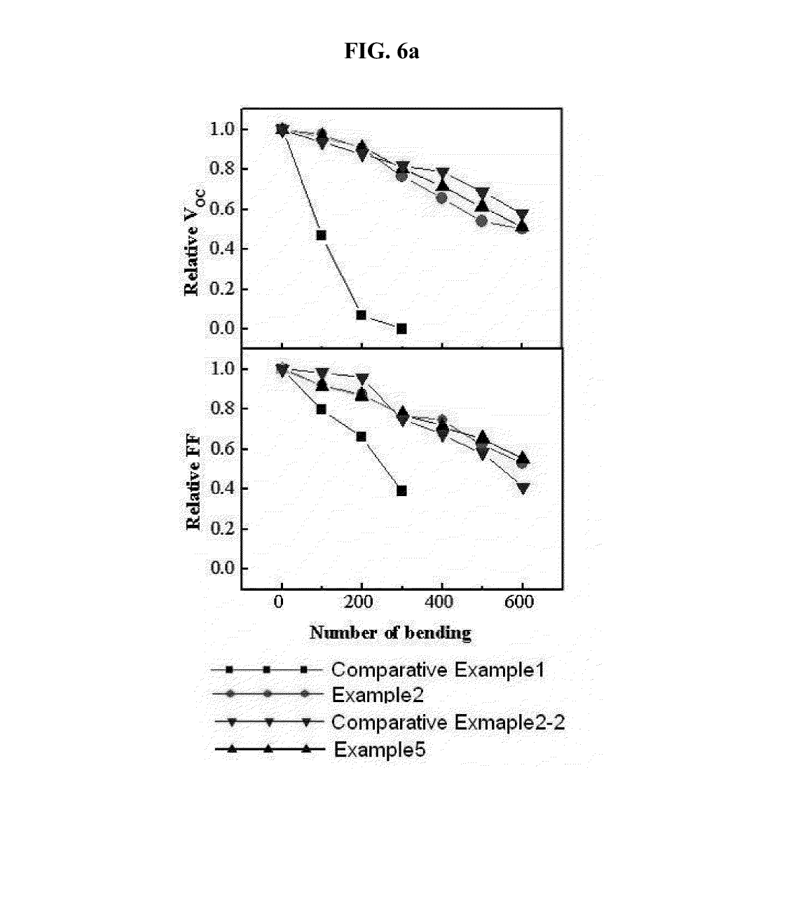

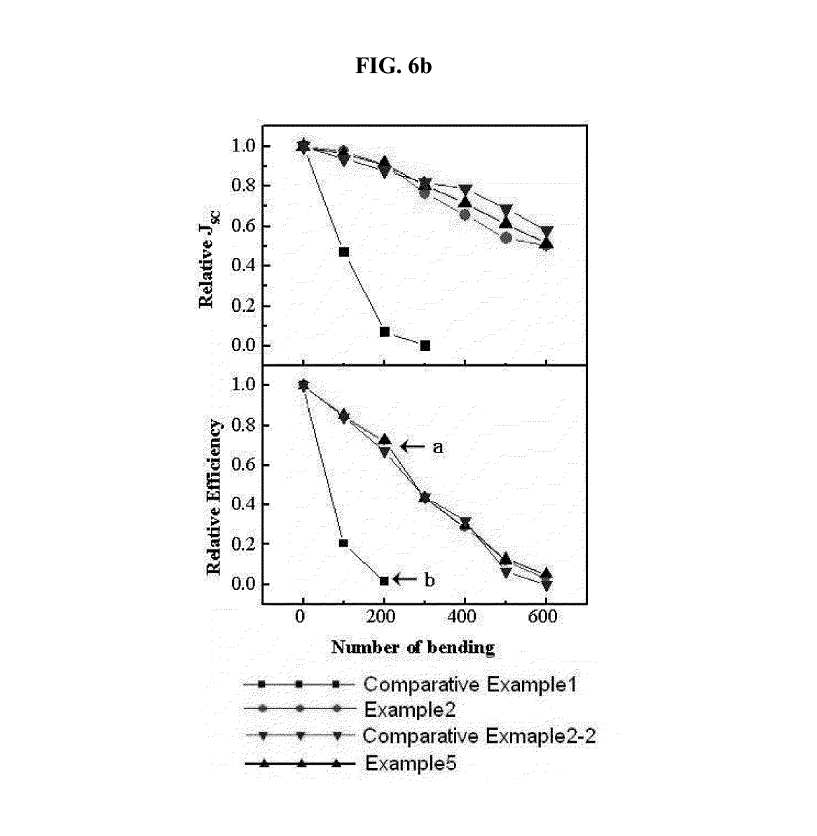

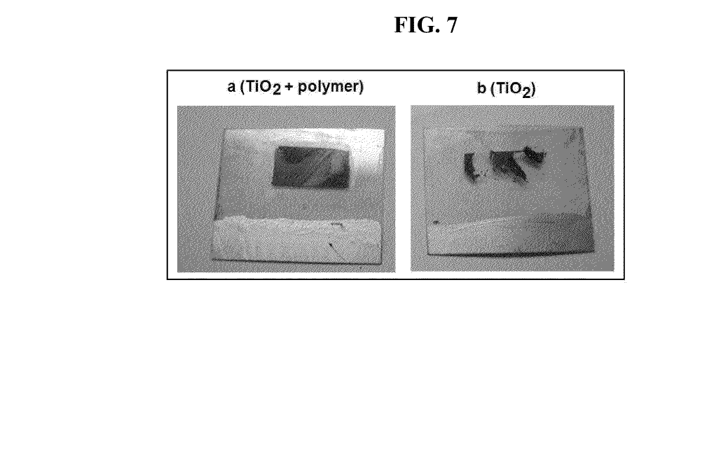

In FIGS. 6a and 6b, current-voltage curves of Comparative Examples 1 and 2-2 and Examples 2 and 5 according to bending test under AM 1.5G 1 Sun are shown. And, the film state of the dye-sensitized solar cell after external bending test of Example 5(a) and Comparative Example 1(B) are compared in FIG. 7.

TABLE 1

| | | | Fill | | | TiO₂ |
|---|---|---|---|---|---|---|
| | | | factor | Effi- | | thick- |
| | Jsc | Voc | (FF) | ciency | Area | ness |
| | (mA/cm²) | (V) | (%) | (%) | (cm²) | (μm) |
| Comparative | 9.30 | 0.750 | 0.643 | 4.49 | 0.383 | 6.4 |
| Example 1 | | | | | | |
| Comparative | 8.75 | 0.752 | 0.625 | 4.11 | 0.44 | 6.6 |
| Example 2-1 | | | | | | |
| (PMMA 1 wt %) | | | | | | |
| Comparative | 7.34 | 0.753 | 0.649 | 3.59 | 0.42 | 6.4 |
| Example 2-2 | | | | | | |
| (PMMA 3 wt %) | | | | | | |
| Comparative | 7.01 | 0.755 | 0.651 | 3.45 | 0.417 | 6.3 |
| Example 2-3 | | | | | | |
| (PMMA 5 wt %) | | | | | | |
| Example 1 | 9.18 | 0.753 | 0.645 | 4.46 | 0.434 | 6.7 |
| (PMMA 1 wt %) | | | | | | |
| Example 2 | 8.85 | 0.760 | 0.664 | 4.46 | 0.305 | 6.5 |
| (PMMA 3 wt %) | | | | | | |
| Example 3 | 8.23 | 0.774 | 0.682 | 4.34 | 0.391 | 6.4 |
| (PMMA 5 wt %) | | | | | | |
| Example 4 | 9.12 | 0.754 | 0.652 | 4.49 | 0.371 | 6.3 |
| (PVP 1 wt %) | | | | | | |
| Example 5 | 8.54 | 0.760 | 0.605 | 3.93 | 0.422 | 6.5 |
| (PVP 3 wt %) | | | | | | |
| Example 6 | 7.89 | 0.742 | 0.618 | 3.62 | 0.354 | 6.6 |
| (PVP 5 wt %) | | | | | | |

As shown in the above Table 1 and FIG. 4, the dye-sensitized solar cells of Examples 1 to 3 using photoelectrodes comprising polymer (polymethylmethacrylate (PMMA)) exhibit equivalent efficiency to the dye-sensitized solar cell of Comparative Example which does not use polymer. And, when polymer (polyvinylpyrrolidone (PVP)) is introduced respectively in an amount of 1 wt %, 3 wt %, and 5 wt % (Examples 4 to 6), rate of decrease in photocurrent density (J_{SC}) was respectively 2%, 8% and 15%, compared to the existing dye-sensitized solar cell of Comparative Example 1 which does not use polymer. Due to the decrease in photocurrent density (J_{SC}), Examples 4 to 6 exhibit efficiency decrease of 0%, 12% and 19%, thus it can be seen that the present invention exhibits good property.

And, when a cell is manufactured by introducing polymer by the method of Comparative Example 2, Comparative Examples 2-1˜2-3 exhibited much decrease in photocurrent density (J_{SC}) compared to Comparative Example 1 (specifically, rate of decrease in photocurrent density (J_{SC}) was respectively 6%, 21% and 25%, and efficiency decrease was respectively 8%, 20% and 23%). Therefore, it can be seen that the method of the present invention is more excellent than the method of Comparative Example 2. Namely, since Comparative Example 2 initially mixes polymer in the paste when manufacturing a photoelectrode, although similar property was exhibited to external bending compared to Comparative Example 1, there is a limit in cell efficiency improvement.

To the contrary, Examples 1 to 6 have excellent external bending property while exhibiting high efficiency because the process is simple and the decrease rate in cell efficiency according to polymer content is low, and thus, a flexible dye-sensitized solar cell having excellent properties may be manufactured.

Particularly, as can be seen from the external bending test results of FIG. 5a and FIG. 5b, there was significant difference between the results if coating is progressed on a dye-adsorbed metal oxide nanoparticle layer using a polymer solution for manufacturing a photoelectrode (Examples 1 to 3) and if that is not the case (Comparative Example 1). Specifically, comparing the cell properties of Examples 1 to 3 and the result of Comparative Example 1, for bending 200 times, Comparative Example 1 which does not use polymer did not work at all with efficiency of 0%. To the contrary, Examples 1 to 3 exhibited 47-79% efficiency according to polymer content of cells. Therefore, the present invention may embody a flexible dye-sensitized solar cell having high photoelectric efficiency while securing stability of the semiconductor film layer.

Further, as can be seen from the external bending test results of FIG. 6a and FIG. 6b, comparing the results if coating is progressed on the dye-adsorbed metal oxide nanoparticle layer using the same amount of polymer for manufacturing a flexible photoelectrode (Examples 2, 5) and if that is not the case (Comparative Example 1, Comparative Example 2-2), for 200 times bending, Comparative Example 1 which does not use polymer did not work at all with 0% efficiency identically to the results of FIGS. 5a and 5b. To the contrary, the cells of Comparative Example 2-2 and Examples 2 and 5 exhibited similar efficiency, but Comparative Example 2-2 was not effective because cell efficiency was lower than the present invention, as explained above.

And, as shown in the photograph of FIG. 7, after external bending test (200 times bending test), Comparative Example 1(b) which comprises TiO₂ without polymer had decreased adhesion to the substrate and decreased bonding between TiO₂, and thus, film was completely delaminated. Due to the results, photocurrent density and efficiency were decreased in Comparative Example 1. To the contrary, Example 5(a) which comprises TiO₂ coated with polymer did not show significant change in the film state even after external bending test.

Accordingly, according to the present invention, a flexible dye-sensitized solar cell exhibiting high efficiency while maintaining excellent performance similar or equivalent to the existing solar cells in external bending test may be embodied.

### EXPLANATIONS OF REFERENCE NUMERALS

100: flexible dye-sensitized solar cell
110: photoelectrode
101: flexible substrate
102: conductive film
103: conductive flexible substrate
104: porous membrane comprising metal oxide nanoparticles
105: porous membrane comprising dye-adsorbed metal oxide nanoparticles
106: complex of dye-adsorbed metal oxide nanoparticles-polymer
120: counter electrode
101: flexible substrate
102: conductive film
121: catalyst layer
130: electrolyte
140: polymer adhesive layer

What is claimed is:

1. A method for preparing a flexible photoelectrode comprising
(a) forming a porous membrane comprising metal oxide nanoparticles on a flexible substrate coated with a conductive film;
(b) adsorbing dyes on the surface of the metal oxide nanoparticles of the porous membrane; and
(c) coating a polymer solution on the dye-adsorbed metal oxide nanoparticles of the porous membrane and heat treating, to prepare a complex of dye-adsorbed metal oxide nanoparticles-polymer where polymer is penetrated between the metal oxide nanoparticels of the porous membrane.

2. The method for preparing a flexible photoelectrode according to claim 1, wherein the rate of decrease in photoelectric conversion efficiency (%) after 100 to 300 times bending test using a bending tester with a diameter of 7 mm is 50% or less compared to initial efficiency.

3. The method for preparing a flexible photoelectrode according to claim 1, wherein the polymer solution is a colloidal solution where 0.01 to 10 wt % of a polymer is dispersed in a solvent, based on the total polymer solution.

4. The method for preparing a flexible photoelectrode according to claim 1, wherein the polymer solution includes at least one polymer selected from the group consisting of polyurethane, polyethylene oxide, polyvinyl pyrrolidone, polypropylene oxide, polyethylene glycol, chitosan, chitin, polyacrylamide, polyvinyl alcohol, polyacrylic acid, cellulose, ethyl cellulose, polyhydroxy ethylmethacrylate, polymethyl methacrylate, polysaccharide, polyamide, polycarbonate, polyethylene, polypropylene, polystyrene, polyethyleneterephthalate, polyethylene naphthalate, a silicon-containing polymer comprising polydimethyl siloxane, isoprene, butadiene-based rubber and a derivative thereof.

5. The method for preparing a flexible photoelectrode according to claim 3, wherein the solvent is selected from the group consisting of ethanol, methanol, terpineol, lauric acid, ethyl acetate, hexane and toluene.

6. The method for preparing a flexible photoelectrode according to claim 1, wherein the coating of the polymer solution is performed by spin coating, slit coating or dip coating.

7. The method for preparing a flexible photoelectrode according to claim 1, wherein the heat treatment is conducted at a temperature of from 20° C. to 150° C. for 10 to 30 minutes.

8. The method for preparing a flexible photoelectrode according to claim 1, wherein the flexible substrate is
a plastic substrate selected from the group consisting of polyethylene terephthalate; polyethylene naphthalate; polycarbonate; polypropylene; polyimide; triacetylcellulose, polyethersulfone, organically modified silicate of a three dimensional network structure formed by hydrolysis and condensation reaction of organometal alkoxide of at least one selected from the group consisting of methyltriethoxy silane, ethyl triethoxy silane and propyltriethoxysilane; a copolymer thereof; and a mixture thereof, or
a metal flexible substrate comprising one selected from the group consisting of iron, stainless steel, aluminum, titanium, nickel, copper and tin.

9. The method for preparing a flexible photoelectrode according to claim 1, wherein the porous membrane includes metal oxide nanoparticles selected from the group consisting of tin (Sn) oxide, antimony (Sb), niobium (Nb) or fluorine-doped tin (Sn) oxide, indium (In) oxide, tin-doped indium (In) oxide, zinc (Zn) oxide, aluminum (Al), boron (B), gallium (Ga), hydrogen (H), indium (In), yttrium (Y), titanium (Ti), silicon (Si) or tin (Sn)-doped zinc (Zn) oxide, magnesium (Mg) oxide, cadmium (Cd) oxide, magnesium zinc (MgZn) oxide, indium zinc (InZn) oxide, copper aluminum (CuAl) oxide, silver (Ag) oxide, gallium (Ga) oxide, zinc tin oxide (ZnSnO), titanium oxide (TiO₂) and zinc indium tin (ZIS) oxide, nickel (Ni) oxide, rhodium (Rh) oxide, ruthenium (Ru) oxide, iridium (Ir) oxide, copper (Cu) oxide, cobalt (Co) oxide, tungsten (W) oxide, titanium (Ti) oxide, zirconium (Zr) oxide, strontium (Sr) oxide, lanthanum (La) oxide, vanadium (V) oxide, molybdenum (Mo) oxide, niobium (Nb) oxide, aluminum (Al) oxide, yttrium (Y) oxide, scandium (Sc) oxide, samarium (Sm) oxide, strontium titanium (SrTi) oxide and a mixture thereof.

10. The method for preparing a flexible photoelectrode according to claim 1, wherein the adsorbing of dyes comprise impregnating the flexible substrate on which a porous membrane comprising the metal oxide nanoparticles is formed in a solution comprising photosensitive dyes for 10 minutes to 24 hours.

11. The method for preparing a flexible photoelectrode according to claim 1, wherein the conductive film comprises SnO₂:F, ITO, a metal electrode having an average thickness of 1 to 1000 nm, metal nitride, metal oxide, a carbon compound, or conductive polymer.

12. The method for preparing a flexible photoelectrode according to claim 10 wherein the metal nitride is selected from the group consisting of nitride of Group IVB metal atom, nitride of Group VB metal atom, nitride of Group VIB metal atom, aluminum nitride, gallium nitride, indium nitride, silicon nitride, germanium nitride, and a mixture thereof.

13. The method for preparing a flexible photoelectrode according to claim 10 wherein the metal oxide is selected from the group consisting of tin (Sn) oxide, antimony (Sb), niobium (Nb) or fluorine-doped tin (Sn) oxide, indium (In) oxide, tin-doped indium (In) oxide, zinc (Zn) oxide, aluminum (Al), boron (B), gallium (Ga), hydrogen (H), indium (In), yttrium (Y), titanium (Ti), silicon (Si) or tin (Sn)-doped zinc (Zn) oxide, magnesium (Mg) oxide, cadmium (Cd) oxide, magnesium zinc (MgZn) oxide, indium zinc (InZn) oxide, copper aluminum (CuAl) oxide, silver (Ag) oxide, gallium (Ga) oxide, zinc tin oxide (ZnSnO), titanium oxide (TiO₂) and zinc indium tin (ZIS) oxide, nickel (Ni) oxide, rhodium (Rh) oxide, ruthenium (Ru) oxide, iridium (Ir) oxide, copper (Cu) oxide, cobalt (Co) oxide, tungsten (W) oxide, titanium (Ti) oxide, and a mixture thereof.

14. The method for preparing a flexible photoelectrode according to claim 10 wherein the carbon compound is selected from the group consisting of activated carbon, graphite, carbon nanotube, carbon black, graphene, and a mixture thereof.

15. The method for preparing a flexible photoelectrode according to claim 10 wherein the conductive polymer is selected from the group consisting of PEDOT (poly(3,4-ethylenedioxythiophene))-PSS(poly(styrenesulfonate)), polyaniline-CSA, pentacene, polyacetylene, P3HT (poly(3-hexylthiophene), polysiloxane carbazole, polyaniline, polyethylene oxide, poly(1-methoxy-4-(0-Disperse Red1)-2,5-phenylene-vinylene, polyindol, poycarbazol, polypyridiazine, polyisothianaphthalene, polyphenylene sulfide, polyvinylpyridine, polythiophene, polyfluorene, polypyridine, polypyrrol, polysulfurnitride, a copolymer thereof, and a mixture thereof.

16. A flexible dye-sensitized solar cell comprising
a counter electrode disposed so as to be opposite to the flexible photoelectrode prepared by the method of claim 1 with spaced apart, and
electrolyte that fills a space between the photoelectrode and the counter electrode,
wherein the photoelectrode comprises a flexible substrate coated with a conductive film, and a complex of dye-adsorbed metal oxide nanoparticle-polymer formed thereon.

17. The flexible dye-sensitized solar cell according to claim 16, wherein the counter electrode comprises a flexible substrate, a conductive film and a catalyst layer formed on the flexible substrate.

18. The flexible dye-sensitized solar cell according to claim 16, wherein the electrolyte is selected from the group consisting of an oxidation-reduction derivative, polymer gel electrolyte containing polymer or inorganic particles, organic hole conductor (HCM, spiro-OMeTAD) and P type semiconductor (CuSCN).

19. The flexible dye-sensitized solar cell according to claim 16, further comprising a heat adhesion polymer film or paste adhesive for sealing the photoelectrode and the counter electrode.
